(19) United States
(12) Patent Application Publication
(10) Pub. No.: US 2004/0191697 A1
(43) Pub. Date: Sep. 30, 2004

(54) Method for processing a niobium type thin film and method for manufacturing a superconducting integrated circuit

(75) Inventors: Hisashi Nakatsuka, Tokyo (JP); Hirotaka Terai, Tokyo (JP); Zhen Wang, Tokyo (JP)

Correspondence Address: VENABLE, BAETJER, HOWARD AND CIVILETTI, LLP, P.O. BOX 34385, WASHINGTON, DC, 20043-9998, US

(73) Assignee: Communications Research Laboratory, Tokyo (JP)

(21) Appl. No.: 10/394,026

(22) Filed: Mar. 24, 2003

(51) Int. Cl. G03F 7/26

(52) U.S. Cl. 430/313; 430/311

(57) ABSTRACT

The present invention provides a processing method for suppressing variation in the characteristics of a Josephson junction using a niobium type thin film. In the processing method of the present invention, CF4 gas to which CHF3 gas has been added is used as the etching gas in reactive ion etching. As a result, the etching rate is lowered so that high-precision etching control is facilitated. In addition, it is desirable that magnesium oxide is used as mask of this etching, because etching amount of the mask become reduced. In the superconducting integrated circuit manufacturing method of the present invention, the processing method of the present invention is used to process the counter-electrode of a Josephson junction. As a result, variation in the junction area can be reduced; accordingly, variation in the characteristics of the Josephson junction can be reduced.

### BACKGROUND OF THE INVENTION

1. Field of the Invention

The present invention relates to a method for the fine processing of thin films formed from niobium type materials. In addition, the present invention relates to a method for manufacturing superconducting integrated circuits using this fine processing method.

2. Description of Related Art

For example, Josephson LSIs are known as superconducting integrated circuits. A Josephson LSI is an integrated circuit in which Josephson elements, i. e., elements that have a Josephson junction, are used as switching elements.

A Josephson junction is a junction structure in which an insulating film is sandwiched between two superconducting thin films. For example, films formed from niobium type materials can be used as superconducting thin films. Examples of niobium type materials that can be used in a Josephson junction include, Nb, NbN, Nb₃Ge, Nb₃Sn and the like.

In order to increase the speed and frequency of a Josephson junction, it is necessary to reduce the capacitance of the Josephson junction. Furthermore, in order to reduce the capacitance of a Josephson junction, it is necessary to reduce the size of the junction.

However, as the size of a Josephson junction is reduced, it becomes difficult to control this size with high precision. Specifically, as the size of a Josephson junction becomes smaller, the variation in the area of the junction increases.

The critical current of a Josephson junction is proportional to the area of the junction portion. Specifically, the characteristics of a Josephson junction depend greatly on the area of the junction portion. Accordingly, variation in this area causes a drop in the reliability and yield of Josephson LSIs.

### SUMMARY OF THE INVENTION

It is a first object of the present invention to provide a fine processing method for the precise patterning of niobium type thin films.

Furthermore, it is a second object of the present invention to provide a method for manufacturing highly reliable superconducting integrated circuits at a high yield.

The method for processing a niobium type thin film of the first invention comprises a masking step of forming a mask pattern on a thin film formed from a niobium type material; and an etching step of processing the niobium type thin film by reactive ion etching using CF4 gas to which CHF3 gas has been added as an etching gas, and using the mask pattern as an etching mask.

In the first invention, CHF3 gas is added to the etching gas. As a result, a fluorocarbon film is formed on the surface of the niobium type thin film. This fluorocarbon film retards the progress of etching by the CF4 gas. Accordingly, the etching rate is lowered, so that control of the amount of etching is facilitated.

The method for manufacturing a superconducting integrated circuit of the second invention comprises a lamination step of forming laminated layers consisting of a first niobium type thin film, an insulating thin film and a second niobium type thin film on a substrate; a counter-electrode formation step which includes a masking step of forming a mask pattern on the second niobium type thin film, and an etching step of processing the niobium type thin film by reactive ion etching using CF4 gas to which CHF3 gas has been added as an etching gas, and using the mask pattern as an etching mask; a base electrode formation step of patterning the first niobium type thin film; and a wiring step of forming a wiring pattern used to wire the counter-electrode and base electrodes.

In the second invention, the processing method of the first invention is used in the step of forming the counter-electrode. As a result, the processing precision of the counter-electrode is improved, so that variation in the characteristics of the Josephson junction can be suppressed. Accordingly, the reliability and yield of the superconducting integrated circuit are improved.

### BRIEF DESCRIPTION OF THE DRAWINGS

Other objects and advantages of the present invention will be described with reference to the attached figures.

FIGS. 1A through 1F are sectional process diagrams which illustrate a Josephson LSI manufacturing method according to a preferred embodiment of the present invention;

FIG. 2 is a sectional view which shows schematically a Josephson junction in which a reduction in size has occurred as a result of over-etching;

FIGS. 3A through 3C are sectional process diagrams which illustrate a fine processing method according to a first embodiment;

FIG. 4 is a graph which shows the relationship between the amount of added CHF3 gas and the etching rate;

FIGS. 5A through 5E are sectional process diagrams which illustrate a fine processing method according to a second embodiment;

FIG. 6 is a graph which shows the characteristics of the Josephson junction array in the second embodiment; and

FIG. 7 is a graph which shows the results obtained when the relationship between the size and variation in the characteristics of the Josephson junction array in the second embodiment was measured.

### DESCRIPTION OF THE PREFERRED EMBODIMENTS

Embodiments of the present invention will be described with reference to the attached figures. In the figures, the sizes, shapes and dispositions of the respective constituent components are merely shown in schematic terms to an extent that is sufficient to allow understanding of the present invention; furthermore, the numerical conditions described below are merely examples.

First Embodiment

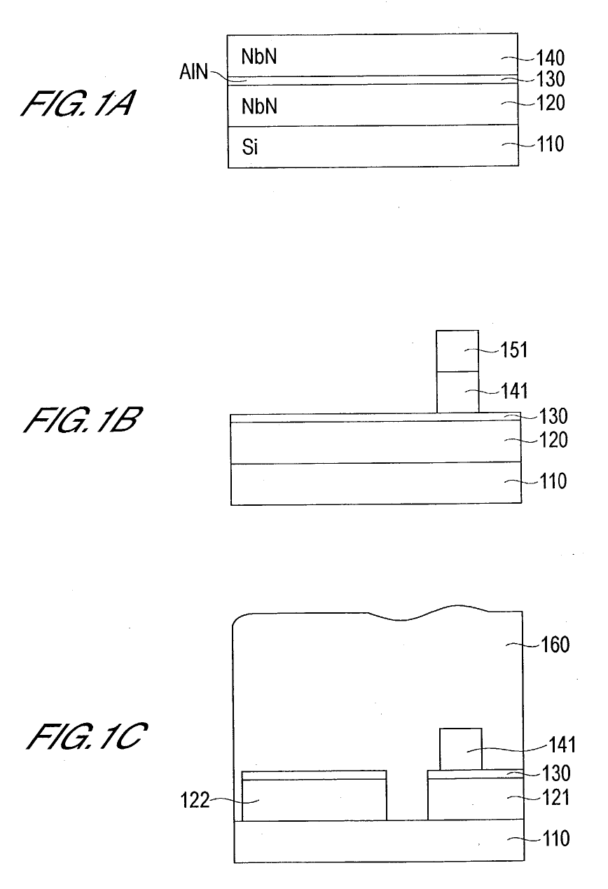

A schematic outline of the Josephson LSI manufacturing method of the present embodiment will be described with reference to FIGS. 1A through IF.

I) First, a laminated film consisting of a niobium nitride (NbN) film 120, an aluminum nitride (AlN) film 130 and a niobium nitride film 140 is formed on a silicon substrate 110 (see FIG. 1A). The thickness of the niobium nitride film 120 is (for example) 300 nm, the thickness of the aluminum nitride film 130 is (for example) several nm, and the thickness of the niobium nitride film 140 is (for example) 200 nm. These films 120, 130 and 140 can be formed using any desired thin film formation techniques. For example, the films 120, 130 and 140 can be formed using a sputtering method.

II) A mask 151 is formed on the upper surface of the niobium nitride film 140. Then, a counter electrode 141 is formed by patterning the niobium nitride film 140 using this mask 151 (see FIG. 1B). This patterning is formed using the fine processing method of the present invention. Details of this patterning will be described later. The mask 151 is removed following the patterning.

III) Nest, base electrodes 121 and 122 are formed by patterning the niobium nitride film 120 (see FIG. 1 (C)). This patterning can be performed using (for example) an ordinary photolithographic technique. For example, reactive ion etching can be used as the etching technique of this patterning. As a result of this step, a Josephson junction consisting of the base electrode 121, aluminum nitride film 130 and counter-electrode 141 is completed. Afterward, a silicon oxide film (SiO2) 160 is formed as an insulating film over the entire surface of the substrate 110 (see FIG. 1 (C)). The thickness of the silicon oxide film 160 is (for example) 1 μm. For example, a deposition technique such as ion beam sputtering or the like can be used to form the silicon oxide film 160.

IV) Next, the surface of the silicon oxide film 160 is smoothed (see FIG. 1D). As a result of this smoothing, the upper surface of the counter electrode 141 is exposed. For example, chemical mechanical polishing (CMP) can be used as the smoothing technique.

V) Next, a contact hole 161 is formed in the silicon oxide film 160 (see FIG. 1E). For example, an ordinary photolithographic technique can be used to form the contact hole 161. Furthermore, for example, reactive ion etching can be used as the etching technique for patterning.

VI) Furthermore, a wiring pattern 170 is formed (see FIG. 1F). The wiring pattern 170 is formed by growing a metal such as niobium nitride or the like over the entire surface o the substrate 110, and then patterning this metal layer. For example, a deposition technique such as ion beam sputtering or the like can be used as the metal growth technique. Patterning can be accomplished using an ordinary photolithographic technique.

VII) Afterward, a Josephson LSI is completed using a universally known process.

Next, the fine processing method (the abovementioned step II) of the present embodiment will be described in detail.

As was described above, the base electrode 121, aluminum nitride film 130 and counter-electrode 141 form a Josephson junction (see FIG. 1C). In order to form a Josephson junction that operates at a high speed and high frequency, it is necessary to reduced the area of the junction. Specifically, it is desirable that the undersurface of the counter-electrode 141 be formed with a small area. A high-precision fine processing technique is required in order to form a counter-electrode 141 whose undersurface has a small area.

A reduction in the size of the junction due to over-etching is important as a factor that causes a deterioration in the processing precision of the counter-electrode 141. As is shown in FIG. 2, over-etching occurs in cases where the progress of etching is more rapid than envisioned. As a result of this over-etching, the side surfaces of the counter-electrode 141 are etched; consequently, the area of the undersurface of the counter-electrode 141 is smaller than the design value. In other words, as a result of such over-etching, a phenomenon in which the area of the Josephson junction is smaller than the design value, i. e., a reduction in size, occurs. As was described above, the characteristics of a Josephson junction depend greatly on the area of the junction portion. Accordingly, a reduction in size caused by over-etching results in variation in the characteristics of the Josephson junction.

In the present embodiment, high-precision fine processing is made possible by performing reactive ion etching using CF4 gas to which CHF3 gas has been added.

FIGS. 3A through 3C are sectional process diagrams which illustrate the patterning step of the niobium nitride film 140 (see FIG. 1B) in detail.

i) First, a resist film 150 is formed over the entire surface of the niobium nitride film 140 using (for example) a spin coating method or the like (see FIG. 3A). For example, SAL601-SR4 manufactured by SHIPLY Co. or the like can be used as the resist material. The thickness of the resist film 150 is (for example) 200 nm.

ii) Next, an etching mask 151 is formed by patterning the resist film 150 using a photolithographic technique (see FIG. 3B). For example, an electron beam direct drawing method can be used as the exposure technique for the resist film 150.

iii) Next, a counter-electrode 141 is formed by patterning the niobium nitride film 140 using a reactive ion etching method (see FIG. 3C). In the present embodiment, as was described above, reactive ion etching is performed using CF4 gas to which CHF3 gas has been added. For example, the flow rate of the CF4 gas is 20 sccm. For reasons that will be described later, it is desirable that the flow rate of the CHF3 gas be set at 3 to 5 sccm. The input power is (for example) 75 watts, and the gas pressure is (for example) 10 pascals.

iv) Finally, the etching mask 151 is removed.

FIG. 4 is a graph which shows the relationship between the amount of CHF3 gas that is added and the etching rate. In FIG. 4, the horizontal axis indicates the amount of CHF3 gas that is added, and the vertical axis indicates the etching rate. As above, the etching conditions in this graph are as follows: flow rate of CF4 gas: 20 sccm, input power: 75 watts, gas pressure: 10 pascals.

As is seen from FIG. 4, the etching rate of the niobium nitride film decreases with an increase in the amount of CHF3 gas that is added. As the etching rate decreases, control of the amount of etching becomes easier, so that it becomes easier to prevent a reduction in size caused by over-etching. According to an investigation performed by the present inventor, it appears that the reason that the etching rate is caused to drop by the addition of CHF3 gas is that a fluorocarbon film is formed on the niobium nitride film. Specifically, it appears that this fluorocarbon film suppresses the etching of the niobium nitride film by the CF4 gas.

The present inventor performed an experiment in which the reduction in size that occurred when 20% over-etching was deliberately performed was measured. In this experiment, etching of the niobium nitride film was performed using a mask pattern with a line and space structure having widths of 2.0 μm, 1.0 μm and 0.5 μm. SAL601-SR4 manufactured by SHIPLY Co. was used as the resist material, and the thickness of the resist film was set at 200 nm. Furthermore, as above, the etching conditions were as follows: flow rate of CF4 gas: 20 sccm, input power: 75 watts, gas pressure: 10 pascals.

As a result, in cases where the flow rate of the CHF3 gas was 3 sccm or greater, there was no under-cutting, i. e., no phenomenon in which the width of the niobium nitride film became narrower than the width of the resist mask 151 (see FIG. 2). Accordingly, it is desirable that the flow rate of the CHF3 gas be 3 sccm or greater.

Compared to the etching rate of the niobium nitride film, the etching rate of the resist film shows little dependence on the CHF3 gas flow rate. Accordingly, if the CHF3 gas flow rate is increased to some extent, the etching rate of the resist film becomes higher than the etching rate of the niobium nitride film. According to an investigation performed by the present inventor, the side surfaces of the resist mask 151 are cut by etching so that the width of the resist mask 151 is reduced in cases where the etching rate of the resist film is too high. The width of the niobium nitride film coincides with the final width of the resist mask 151. Accordingly, in cases where the width of the resist film 151 is reduced, the width of the niobium nitride film is reduced in spite of the fact that no under-cutting occurs. The present inventor investigated the conditions of the CHF3 gas flow rate used to prevent the reduction in size of the counter-electrode 141 due to such a cause. As a result, it appears that it is generally desirable to set the CHF3 gas flow rate at 5 sccm or less.

It appears from the above investigation that the optimal value of the CHF3 gas flow rate is 4 sccm.

If the method for manufacturing of the present embodiment is used, the reduction of the junction area of the Josephson junction can be suppressed. As was described above, the junction area of the Josephson junction is a major factor in determining the critical current value. Accordingly, the method for manufacturing of the present embodiment makes it possible to suppress manufacturing variation in the critical current value.

Second Embodiment

A Josephson LSI manufacturing method according to a second embodiment will be described below.

In the manufacturing method of the present embodiment, the etching mask used in step II differs from that used in the manufacturing method of the first embodiment. The manufacturing steps other than step II (see FIG. 1B) are the same as in the manufacturing method of the first embodiment; accordingly, a description of these steps is omitted.

FIGS. 5A through 5E are sectional process diagrams which illustrate the patterning step of the niobium nitride film 140 in detail.

i) First, a magnesium oxide (MgO) film 510 is formed over the entire surface of the niobium nitride film 140 (see FIG. 5A). The thickness of the magnesium oxide film 510 is for example 1.5 nm. For example, ion beam sputtering can be used as the film formation technique.

ii) Next, a niobium nitride film 520 is formed over the entire surface of the magnesium oxide film 510 (see FIG. 5B). This niobium nitride film 520 is formed in order to ensure the adhesion of the resist film that is formed in the next step. Specifically, the reason for this is that if a resist film is formed directly on the surface of the magnesium oxide film 510, the resist film 530 will tend to peel. The thickness of the niobium nitride film 520 is for example 1.5 nm. For example, a sputtering method can be used as the film formation technique.

iii) A resist film is formed on the upper surface of the niobium nitride film 520. Then, a resist pattern 531 is formed by patterning this resist film using a photolithographic technique (see FIG. 5C). For example, SAL601-SR4 manufactured by SHIPLY Co. or the like can be used as the resist material. The thickness of the resist pattern 531 is for example 200 nm. Furthermore, for example, an electron beam direct drawing method can be used as the exposure technique that is employed when the resist film is patterned.

iv) Next, the magnesium oxide film 510 and niobium nitride film 520 are patterned by etching using the resist pattern 531 as a mask (see FIG. 5D). For example, ion beam etching can be used as the etching technique. As a result, a magnesium oxide mask 511 covered by a niobium nitride film pattern 521 is completed.

v) Afterward, a counter-electrode 141 is formed by patterning the niobium nitride film 140 using a reaction ion etching method (see FIG. 5E). In the present embodiment, as in the first embodiment, reactive ion etching is performed using CF4 gas to which CHF3 gas has been added as the etching gas. For example, the etching conditions are as follows: CF4 gas flow rate: 20 sccm, CHF3 gas flow rate: 3 sccm or greater, input power: 75 watts, gas pressure: 10 pascals.

vi) Finally, the films 511, 521 and 531 are removed.

The present inventor conducted an experiment according to the abovementioned manufacturing conditions i through v, and the reduction in size that occurred when 20% over-etching was deliberately performed was measured. As a result, it was found that there was almost no reduction in the size of the magnesium oxide film 511. Furthermore, as in the first embodiment, no under-cutting of the niobium nitride film (corresponding to the counter-electrode 141) occurred as long as the CHF3 gas flow rate was 3 sccm or greater. The reduction in the size of the niobium nitride film was approximately 0.02 μm or less.

Furthermore, using the manufacturing method of the present embodiment, the present inventor prepared an array in which 1000 Josephson junctions were connected in series, and measured the variation in the characteristics. FIG. 6 is a graph which shows the characteristics of this Josephson junction array. In FIG. 6, the horizontal axis indicates the applied voltage, and the vertical axis indicates the current. In this Josephson junction array, the size (design value) is 0.98 μm square, the critical current is 210 μA, and the critical current density is approximately 21.2 kA/cm².

As is seen from FIG. 6, when the current that flows through the array is smaller than the critical current, no voltage is generated in the Josephson junctions. Then, when the current reaches the vicinity of the critical current, the voltage abruptly rises. The greater the abruptness of this voltage rise, i. e., the smaller the slope of the rectilinear portion α in FIG. 6, the more superior are the characteristics of the Josephson junctions. The present inventor measured the variation in these characteristics, and calculated the standard deviation σ. As a result, it was found that the standard deviation σ in a cases where the size of the Josephson junctions was 0.98 μm square was 4.2%.

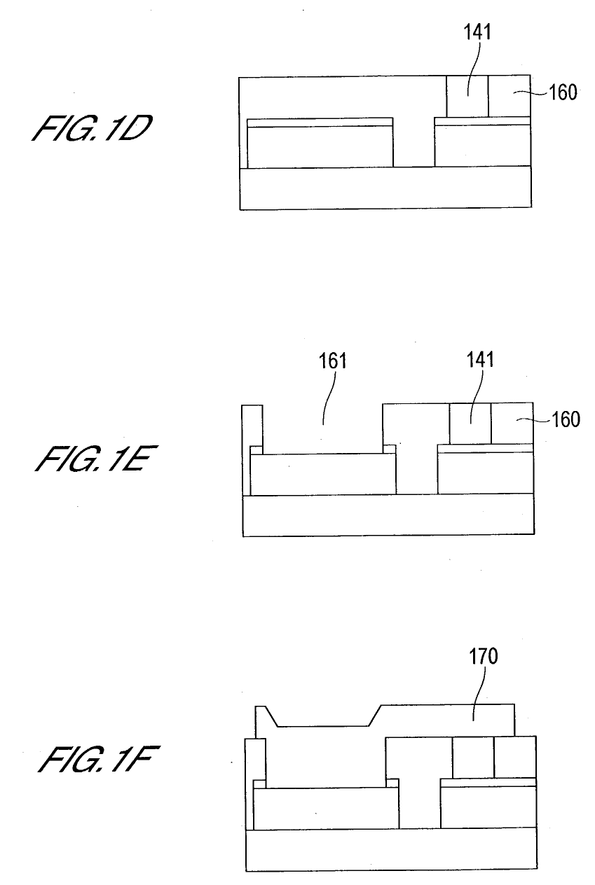

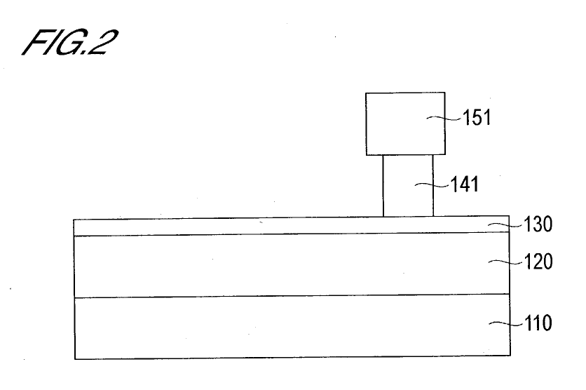

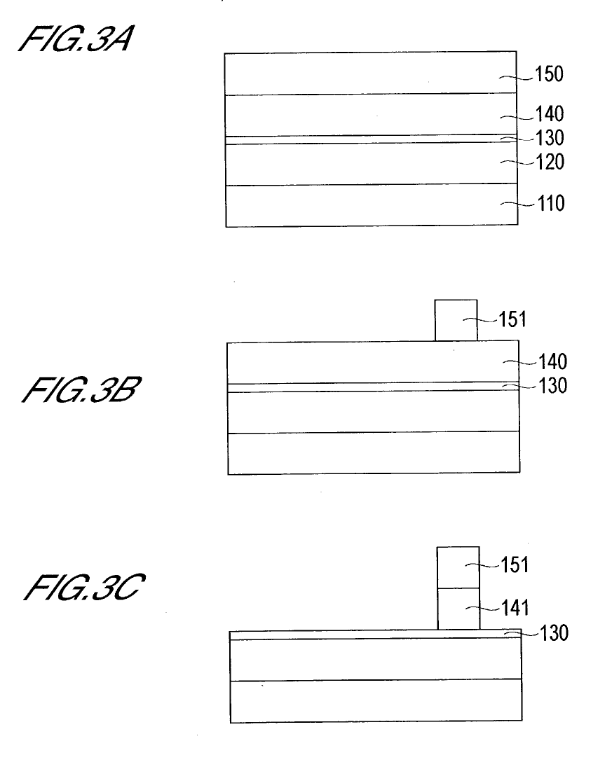

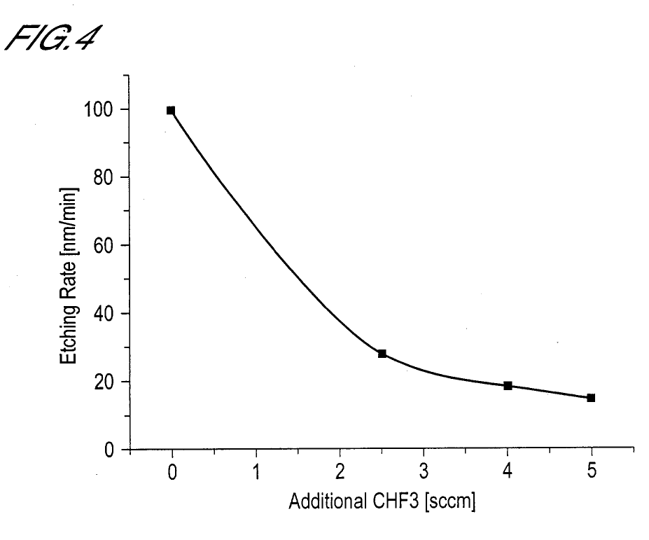

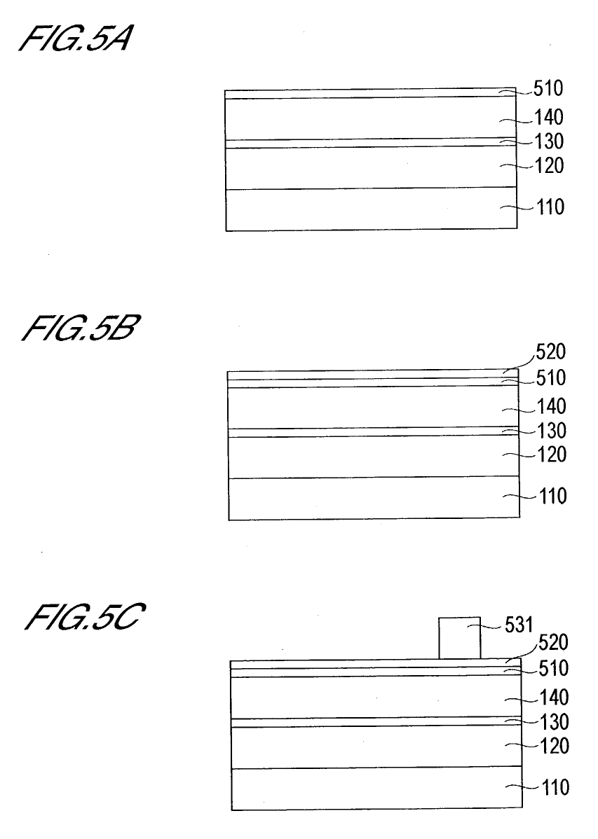

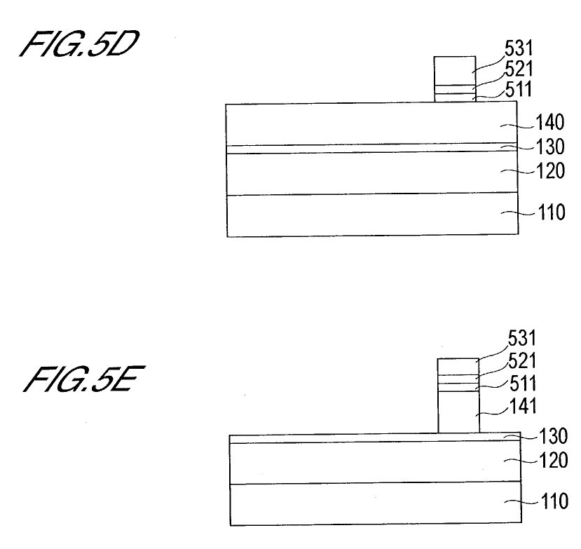

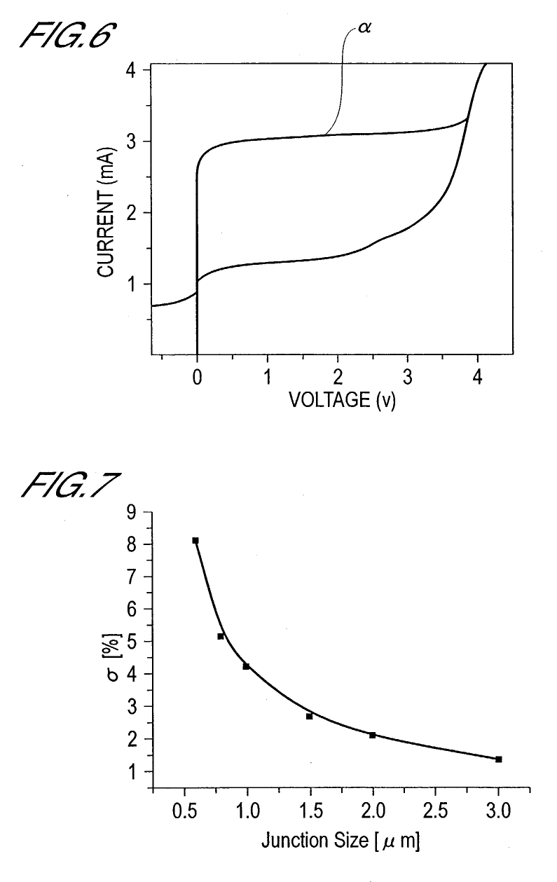

FIG. 7 is a graph which shows the results that were obtained when the relationship between the size of the Josephson junction array and the variation in the characteristics was measured. In FIG. 7, the horizontal axis indicates the size of the Josephson junctions, and the vertical axis indicates the standard deviation σ of the variation in the characteristics.

In the present embodiment, as is clear from FIG. 7, it was possible to suppress the standard deviation σ of the variation in the characteristics to a small value even when the size of the junctions was small.

As was described above, the manufacturing method of the present embodiment makes it possible to suppress the reduction of the junction area of a Josephson junction. As was also described above, the junction area of a Josephson junction is a major factor in determining the critical current value. Accordingly, the manufacturing method of the present embodiment makes it possible to suppress manufacturing variation in the critical current value. According to an investigation conducted by the present inventor, the manufacturing method of the present embodiment makes it possible to control the critical current with sufficient precision even in cases where the dimensions of the Josephson junction are 1 μm or less.

As was described above, the fine processing method of the present invention makes it possible to achieve high-precision patterning of niobium type thin films. In addition, the superconducting integrated circuit manufacturing method of the present invention makes it possible to manufacture highly reliable superconducting integrated circuits at a high yield.

What is claimed is:

1. A method for processing a niobium type thin film comprising:
a masking step of forming a mask pattern on a thin film formed from a niobium type material; and
an etching step of processing said niobium type thin film by reactive ion etching using CF4 gas to which CHF3 gas has been added as an etching gas, and using said mask pattern as an etching mask.

2. The method for processing a niobium type thin film according to claim 1, wherein said masking step comprises:
a first step of forming a resist film on said niobium type thin film; and
a second step of patterning said resist film.

3. The method for processing a niobium type thin film according to claim 1, wherein said masking step comprises:
a first step of forming a magnesium oxide film on said niobium type thin film;
a second step of forming a resist pattern on said magnesium oxide film; and
a third step of patterning said Magnesium oxide film using said resist pattern as a mask.

4. The method for processing a niobium type thin film according to claim 3, wherein said third step is a step of patterning said magnesium oxide film by ion beam etching.

5. The method for processing a niobium type thin film according to claim 3, further comprising a fourth step of forming an adhesive film for ensuring adhesion between said magnesium oxide film and said resist pattern following said first step and prior to said second step.

6. The method for processing a niobium type thin film according to claim 5, wherein said adhesive film is a niobium nitride film.

7. The method for processing a niobium type thin film according to claim 5, wherein said third step is a step of patterning said adhesive film and said Magnesium oxide film simultaneously.

8. The method for processing a niobium type thin film according to claim 1, wherein the flow rate of said CHF3 gas is 3 sccm or greater.

9. The method for processing a niobium type thin film according to claim 1, wherein the flow rate of said CHF3 gas is 5 sccm or less.

10. The method for processing a niobium type thin film according to claim 1, wherein said niobium type thin film is a niobium nitride film.

11. A method for manufacturing a superconducting integrated circuit comprising:
a lamination step of forming laminated layers consisting of a first niobium type thin film, an insulating thin film and a second niobium type thin film on a substrate;
a counter electrode formation step which includes a masking step of forming a mask pattern on said second niobium type thin film, and an etching step of processing said niobium type thin film by reactive ion etching using CF4 gas to which CHF3 gas has been added as an etching gas, and using said mask pattern as an etching mask;
a base electrode formation step of patterning said first niobium type thin film; and
a wiring step of forming a wiring pattern used to wire said counter electrode and said base electrodes.

12. The method for manufacturing a superconducting integrated circuit according to claim 11, wherein said masking step comprises:
a first step of forming a resist film on said niobium type thin film; and
a second step of patterning said resist film.

13. The method for manufacturing a superconducting integrated circuit according to claim 11, wherein said masking step comprises:
a first step of forming a magnesium oxide film on said niobium type thin film;
a second step of forming a resist pattern on said magnesium oxide film; and
a third step of patterning said magnesium oxide film using said resist pattern as a mask.

14. The method for manufacturing a superconducting integrated circuit according to claim 13, wherein said third step is a step of patterning said magnesium oxide film by ion beam etching.

15. The method for manufacturing a superconducting integrated circuit according to claim 13, further comprising a fourth step of forming an adhesive film for ensuring adhesion between said magnesium oxide film and said resist pattern following said first step and prior to said second step.

16. The method for manufacturing a superconducting integrated circuit according to claim 15, wherein said adhesive film is a niobium nitride film.

17. The method for manufacturing a superconducting integrated circuit according to claim 15, wherein said third step is a step of patterning said adhesive film and said Magnesium oxide film simultaneously.

18. The method for manufacturing a superconducting integrated circuit according to claim 11, wherein the flow rate of said CHF3 gas is 3 sccm or greater.

19. The method for manufacturing a superconducting integrated circuit according to claim 11, wherein the flow rate of said CHF3 gas is 5 sccm or less.

20. The method for manufacturing a superconducting integrated circuit according to claim 11, wherein said niobium type thin film is a niobium nitride film.
